(19) United States
(12) Patent Application Publication
(10) Pub. No.: US 2022/0069532 A1
(43) Pub. Date: Mar. 3, 2022

(54) ELECTRONIC SOCKET PIN FOR SELF-RETENTION TO A CONDUCTIVE INTERPOSER

(71) Applicant: Intel Corporation, Santa Clara, CA (US)

(72) Inventors: Feroz Mohammad, Chandler, AZ (US); Steven Klein, Chandler, AZ (US); Srikant Nekkanty, Chandler, AZ (US)

(73) Assignee: Intel Corporation, Santa Clara, CA (US)

(21) Appl. No.: 17/008,979

(22) Filed: Sep. 1, 2020

(51) Int. Cl. H01R 33/76; H01L 23/498; H01L 23/32

(52) U.S. Cl. CPC H01R 33/7685; H01L 23/3675; H01L 23/32; H01L 23/49833

(57) ABSTRACT

An integrated circuit assembly may be formed comprising an electronic socket having at least one conductive pin, wherein a portion of the conductive pin extends from the electronic socket. The integrated circuit assembly further comprises a conductive interposer including at least one conductive via having a conductive layer on a sidewall thereof. The conductive interposer is abutted against the electronic socket, such that the at least one conductive pin is inserted into the at least one conductive via and is biased against the conductive layer of the at least one conductive via. In further embodiments, an integrated circuit package may be electrically attached to the conductive interposer.

### TECHNICAL FIELD

Embodiments of the present description generally relate to the field of integrated circuit assembly fabrication, and, more specifically, to the fabrication of an electronic socket in conjunction with a conductive interposer for attaching an integrated circuit package to a carrier substrate.

### BACKGROUND

The integrated circuit industry is continually striving to produce ever faster, smaller, and thinner integrated circuit packages for use in various electronic products, including, but not limited to, computer servers and portable products, such as portable computers, electronic tablets, cellular phones, digital cameras, and the like.

Such integrated circuit packages may be electrically attached to an electronic substrate through an electronic socket mounted to the electronic substrate. However, current electronic socket designs may have limits with regard to density/pitch scaling of pins (electrical connection structures) and electrical performance scaling. As will be understood, there are a limited number of pins that can be formed through the electronic socket to provide conductive routes between the integrated circuit package and the electronic substrate, depending on the design of the electronic socket. This can create significant constraints with regard to mounting high input/output integrated circuit packages using these electronic sockets.

Furthermore, integrated circuit packages are generally electrically connected to electronic sockets by biasing the integrated circuit packages toward (vertically/z-direction) the electronic sockets with retention mechanisms, wherein conductive structures of the integrated circuit package are pressed (loaded) against resilient/spring structures of the electronic socket to form electrical interconnection. As will be understood to those skilled in the art, the higher the number of electrical interconnections, the higher the retention load that is required to ensure sufficient electrical connection between the conductive structures of the integrated circuit package and the resilient/spring structures of the electronic socket. With a higher retention load, load distribution issues arise, which can affect reliability. Furthermore, higher retention loads also require larger retention mechanisms, which consume valuable space within an electronic product.

### BRIEF DESCRIPTION OF THE DRAWINGS

The subject matter of the present disclosure is particularly pointed out and distinctly claimed in the concluding portion of the specification. The foregoing and other features of the present disclosure will become more fully apparent from the following description and appended claims, taken in conjunction with the accompanying drawings. It is understood that the accompanying drawings depict only several embodiments in accordance with the present disclosure and are, therefore, not to be considered limiting of its scope. The disclosure will be described with additional specificity and detail through use of the accompanying drawings, such that the advantages of the present disclosure can be more readily ascertained, in which:

FIG. 1 is a side cross-sectional view of an integrated circuit assembly, according to one embodiment of the present description.

FIG. 2 is a side cross-sectional view of an integrated circuit assembly, according to another embodiment of the present description.

FIGS. 3-5 are side cross-sectional views of the fabrication of an integrated circuit module, according to an embodiment of the present description.

FIG. 6 is a side cross-sectional view of a conductive pin, according to another embodiment of the present description.

FIG. 7 is an electronic system, according to an embodiment of the present description.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. It is to be understood that the various embodiments, although different, are not necessarily mutually exclusive. For example, a particular feature, structure, or characteristic described herein, in connection with one embodiment, may be implemented within other embodiments without departing from the spirit and scope of the claimed subject matter. References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, it is to be understood that the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled. In the drawings, like numerals refer to the same or similar elements or functionality throughout the several views, and that elements depicted therein are not necessarily to scale with one another, rather individual elements may be enlarged or reduced in order to more easily comprehend the elements in the context of the present description.

The terms “over”, “to”, “between” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The term “package” generally refers to a self-contained carrier of one or more dice, where the dice are attached to the package substrate, and may be encapsulated for protection, with integrated or wire-boned interconnects between the dice and leads, pins or bumps located on the external portions of the package substrate. The package may contain a single die, or multiple dice, providing a specific function. The package is usually mounted on a printed circuit board for interconnection with other packaged integrated circuits and discrete components, forming a larger circuit.

Here, the term “cored” generally refers to a substrate of an integrated circuit package built upon a board, card or wafer comprising a non-flexible stiff material. Typically, a small printed circuit board is used as a core, upon which integrated circuit device and discrete passive components may be soldered. Typically, the core has vias extending from one side to the other, allowing circuitry on one side of the core to be coupled directly to circuitry on the opposite side of the core. The core may also serve as a platform for building up layers of conductors and dielectric materials.

Here, the term “coreless” generally refers to a substrate of an integrated circuit package having no core. The lack of a core allows for higher-density package architectures, as the through-vias have relatively large dimensions and pitch compared to high-density interconnects.

Here, the term “land side”, if used herein, generally refers to the side of the substrate of the integrated circuit package closest to the plane of attachment to a printed circuit board, motherboard, or other package. This is in contrast to the term “die side”, which is the side of the substrate of the integrated circuit package to which the die or dice are attached.

Here, the term “dielectric” generally refers to any number of non-electrically conductive materials that make up the structure of a package substrate. For purposes of this disclosure, dielectric material may be incorporated into an integrated circuit package as layers of laminate film or as a resin molded over integrated circuit dice mounted on the substrate.

Here, the term “metallization” generally refers to metal layers formed over and through the dielectric material of the package substrate. The metal layers are generally patterned to form metal structures such as traces and bond pads. The metallization of a package substrate may be confined to a single layer or in multiple layers separated by layers of dielectric.

Here, the term “bond pad” generally refers to metallization structures that terminate integrated traces and vias in integrated circuit packages and dies. The term “solder pad” may be occasionally substituted for “bond pad” and carries the same meaning.

Here, the term “solder bump” generally refers to a solder layer formed on a bond pad. The solder layer typically has a round shape, hence the term “solder bump”.

Here, the term “substrate” generally refers to a planar platform comprising dielectric and metallization structures. The substrate mechanically supports and electrically couples one or more IC dies on a single platform, with encapsulation of the one or more IC dies by a moldable dielectric material. The substrate generally comprises solder bumps as bonding interconnects on both sides. One side of the substrate, generally referred to as the “die side”, comprises solder bumps for chip or die bonding. The opposite side of the substrate, generally referred to as the “land side”, comprises solder bumps for bonding the package to a printed circuit board.

Here, the term “assembly” generally refers to a grouping of parts into a single functional unit. The parts may be separate and are mechanically assembled into a functional unit, where the parts may be removable. In another instance, the parts may be permanently bonded together. In some instances, the parts are integrated together.

Throughout the specification, and in the claims, the term “connected” means a direct connection, such as electrical, mechanical, or magnetic connection between the things that are connected, without any intermediary devices.

The term “coupled” means a direct or indirect connection, such as a direct electrical, mechanical, magnetic or fluidic connection between the things that are connected or an indirect connection, through one or more passive or active intermediary devices.

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and it is understood that recitations of “top”, “bottom”, “above” and “below” refer to relative positions in the z-dimension with the usual meaning. However, it is understood that embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional”, “profile” and “plan” correspond to orthogonal planes within a cartesian coordinate system. Thus, cross-sectional and profile views are taken in the x-z plane, and plan views are taken in the x-y plane. Typically, profile views in the x-z plane are cross-sectional views. Where appropriate, drawings are labeled with axes to indicate the orientation of the figure.

Embodiments of the present description include an integrated circuit assembly comprising an electronic socket having at least one conductive pin, wherein a portion of the conductive pin extends from the electronic socket. The integrated circuit assembly further comprises a conductive interposer including at least one conductive via having a conductive layer on a sidewall thereof. The conductive interposer is abutted against the electronic socket, such that the at least one conductive pin is inserted into the at least one conductive via and is biased against the conductive layer of the at least one conductive via. In further embodiments, an integrated circuit package may be electrically attached to the conductive interposer.

The embodiments of the present description need no retention mechanism to attach the integrated circuit package to the electronic socket, which results in less required space within an electronic product and reduced cost. Furthermore, the embodiments of the present description may allow for closer conductive pin configurations within the socket and due to the mechanism of the electrical connection can result in better signal integrity.

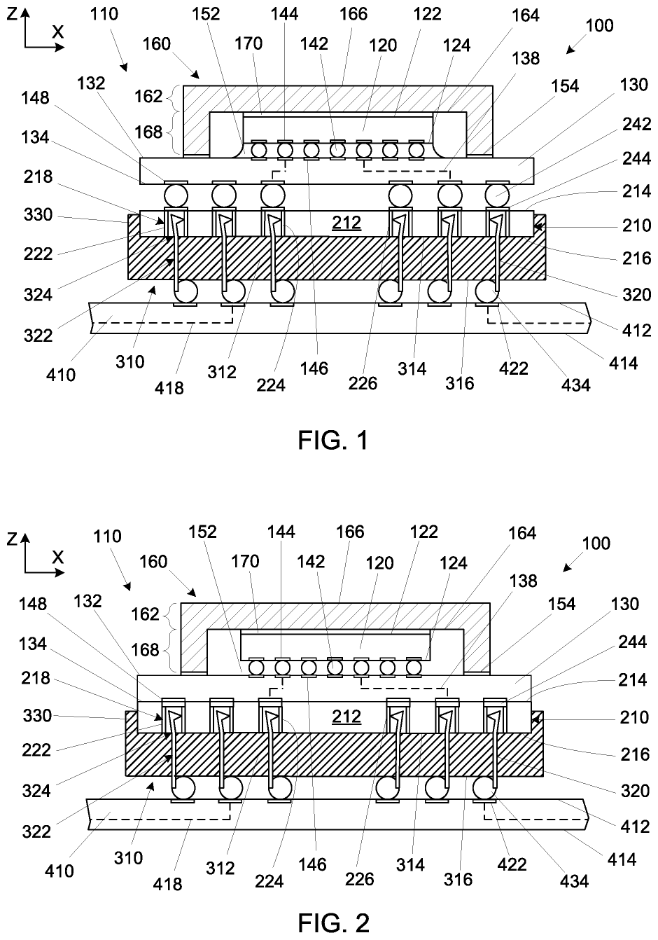

FIG. 1 illustrates an integrated circuit assembly 100 having an integrated circuit package 110 electrically attached to a carrier substrate 410 through a conductive interposer 210 and an electronic socket 310. The integrated circuit package 110 may include at least one integrated circuit device 120 electrically attached to an electronic substrate 130 in a configuration generally known as a flip-chip or controlled collapse chip connection (“C4”) configuration, according to an embodiment of the present description.

The electronic substrate 130 may be any appropriate structure, including, but not limited to, an interposer. The electronic substrate 130 may have a first surface 132 and an opposing second surface 134. The electronic substrate 130 may comprise a plurality of dielectric material layers (not shown), which may include build-up films and/or solder resist layers, and may be composed of an appropriate dielectric material, including, but not limited to, bismaleimide triazine resin, fire retardant grade 4 material, polyimide material, silica filled epoxy material, glass reinforced epoxy material, and the like, as well as low-k and ultra low-k dielectrics (dielectric constants less than about 3.6), including, but not limited to, carbon doped dielectrics, fluorine doped dielectrics, porous dielectrics, organic polymeric dielectrics, and the like.

The electronic substrate 130 may further include conductive routes 138 (shown in dashed lines) extending through the electronic substrate 130. As will be understood to those skilled in the art, the conductive routes 138 may be a combination of conductive traces (not shown) and conductive vias (not shown) extending through the plurality of dielectric material layers (not shown). These conductive traces and conductive vias are well known in the art and are not shown in FIG. 1 for purposes of clarity and conciseness. The conductive traces and the conductive vias may be made of any appropriate conductive material, including but not limited to, metals, such as copper, silver, nickel, gold, and aluminum, alloys thereof, and the like. As will be understood to those skilled in the art, the electronic substrate 130 may be a cored substrate or a coreless substrate. In one embodiment of the present description, the electronic substrate 130 may comprise a silicon or glass interposer. In another embodiment of the present description, the electronic substrate 130 may include active and/or passive devices.

The integrated circuit device 120 may be any appropriate device, including, but not limited to, a microprocessor, a chipset, a graphics device, a wireless device, a memory device, an application specific integrated circuit, combinations thereof, stacks thereof, or the like. Furthermore, the integrated circuit device 120 may be a monolithic die or a die stack that can consist of two or more vertical levels of dice stacked on top of each other, and may include additional materials, such as a mold compound, between at least two of the dice. As shown, the integrated circuit device 120 may have a first surface 122, and an opposing second surface 124.

In an embodiment of the present description, the integrated circuit device 120 may be electrically attached to the electronic substrate 130 with a plurality of device-to-substrate interconnects 142. In one embodiment of the present description, the device-to-substrate interconnects 142 may extend between bond pads 146 on the first surface 132 of the electronic substrate 130 and bond pads 144 on the first surface 122 of the integrated circuit device 120. The device-to-substrate interconnects 142 may be any appropriate electrically conductive material or structure, including, but not limited to, solder balls, metal bumps or pillars, metal filled epoxies, or a combination thereof. In one embodiment, the device-to-substrate interconnects 142 may be solder balls formed from tin, lead/tin alloys (for example, 63% tin/37% lead solder), and high tin content alloys (e.g. 90% or more tin—such as tin/bismuth, eutectic tin/silver, ternary tin/silver/copper, eutectic tin/copper, and similar alloys). In another embodiment, the device-to-substrate interconnects 142 may be copper bumps or pillars. In a further embodiment, the device-to-substrate interconnects 142 may be metal bumps or pillars coated with a solder material. In still a further embodiment, the device-to-substrate interconnects 142 may be anisotropic conductive film.

The bond pads 144 may be in electrical communication with integrated circuitry (not shown) within the integrated circuit device 120. The bond pads 146 on the first surface 132 of the electronic substrate 130 may be in electrical contact with the conductive routes 138. The conductive routes 138 may extend through the electronic substrate 130 and be connected to bond pads 148 on the second surface 134 of the electronic substrate 130. As will be understood to those skilled in the art, the electronic substrate 130 may reroute a fine pitch (center-to-center distance between the bond pads) of the integrated circuit device bond pads 146 to a relatively wider pitch of the bond pads 148 on the second surface 134 of the electronic substrate 130.

An electrically-insulating underfill material 152, such as an epoxy material, may be disposed between the integrated circuit device 120 and the electronic substrate 130. The underfill material 152 may be used to overcome the mechanical stress issues that can arise from thermal expansion mismatch between the electronic substrate 130 and the integrated circuit device 120. As will be understood to those skilled in the art, the underfill material 152 may be dispensed between the first surface 122 of the integrated circuit device 120 and the electronic substrate 130 as a viscous liquid and then hardened with a curing process.

As further shown in FIG. 1, the integrated circuit package 110 may further include a heat dissipation device 160 having a thermal contact surface 164 that is thermally coupled with the second surface 124 of the integrated circuit device 120 with a thermal interface material 170. In one embodiment of the present description, the heat dissipation device 160 may be an integrated heat spreader comprising a main body 162, having the thermal contact surface 164 and an opposing exterior surface 166, and at least one boundary wall 168 extending from the thermal contact surface 164 of the main body 162 of the heat dissipation device 160. The at least one boundary wall 168 may be attached or sealed to the first surface 132 of the electronic substrate 130 with an attachment adhesive or sealant layer 154. The heat dissipation device 160 may be made of any appropriate thermally conductive material, including, but not limited to, at least one metal material and alloys of more than one metal, or highly doped glass or highly conductive ceramic material, such as aluminum nitride. In a specific embodiment of the present description, the heat dissipation device 160 may comprise copper, nickel, aluminum, alloys thereof, laminated metals including coated materials (such as nickel coated copper), and the like.

As illustrated in FIG. 1, the heat dissipation device 160 may be a single material throughout, such as when the heat dissipation device 160, including the heat dissipation boundary wall 168, is formed by a single process step, including but not limited to, stamping, skiving, molding, and the like. However, embodiments of the present description may also include heat dissipation device 160 made of more than one component. For example, the heat dissipation device boundary wall 168 may be formed separately from the main body 162, then attached together to form the heat dissipation device 160. In one embodiment of the present description, the boundary wall 168 may be a single “picture frame” structure surrounding the integrated circuit device 120.

The attachment adhesive 154 may be any appropriate material, including, but not limited to, silicones (such as polydimethylsiloxane), epoxies, and the like. It is understood that the boundary wall 168 not only secures the heat dissipation device 160 to the electronic substrate 130, but also maintains a desired distance between the thermal contact surface 164 of the heat dissipation device 160 and the second surface 124 of the integrated circuit device 120.

The heat dissipation device 160 may be made of any appropriate thermally conductive material, including, but not limited to at least one metal material and alloys of more than one metal, or highly doped glass or highly conductive ceramic material, such as aluminum nitride. In a specific embodiment of the present description, the heat dissipation device 160 may comprise copper, nickel, aluminum, alloys thereof, laminated metals including coated materials (such as nickel coated copper), and the like. At least one additional thermal management device (not shown) may be attached to an exterior surface 166 of the heat dissipation device 160 to enhance heat removal. Such additional thermal management devices may include, but are not limited to, heat pipes, high surface area dissipation structures with a fan (such as a structure having fins or pillars/columns formed in a thermally conductive structure), liquid cooling devices, and the like. Furthermore, although an integrated heat spreader is illustrated in FIG. 1, the heat dissipation device 160 may be a heat pipe, a vapor chamber, a liquid cooling device, a cold plate, and the like.

In various embodiments of the present description, the thermal interface material 170 may be any appropriate, thermally conductive material, including, but not limited to, a thermal grease, a thermal gap pad, a polymer, an epoxy filled with high thermal conductivity fillers, such as metal particles or silicon particles, and the like. In one embodiment of the present description, the thermal interface material 170 may be a phase change material. A phase change material is a substance with a high heat of fusion, which, when it melts and solidifies, is capable of storing and releasing large amounts of thermal energy. In an embodiment of the present description, the phase change material may include, but not limited to, nonadecane, decanoic (capric) acid, eicosane, dodecanoic (lauric) acid, docosane, paraffin wax, stearic acid, tetradecanoic (myristic) acid, octadecanol, hexadecanoic (palmitic) acid, and metallic alloys which include one or more of bismuth, lead, tin, cadmium, antimony, indium, thallium, tellurium, selenium, gallium, mercury, and combinations thereof.

As further shown in FIG. 1, the integrated circuit package 110 may be electrically attached to an electronic socket 310 through a conductive interposer 210. The conductive interposer 210 may comprise an electrically insulative substrate 212 having a first surface 214 and an opposing second surface 216, and at least one conductive via 218 extending between the first surface 214 and the second surface 216. Each conductive via 218 may comprise a conductive layer 222 lining at least one sidewall 226 of an opening 224 that extends between the first surface 214 and the second surface 216 of the electrically insulative substrate 212. The electrically insulative substrate 212 may comprise any appropriate dielectric material, including, but not limited to, bismaleimide triazine resin, fire retardant grade 4 material, polyimide material, silica filled epoxy material, glass reinforced epoxy material, and the like. In one embodiment, the electrically insulative substrate 212 may comprise a solid core having solder resist material on the first surface 214 and on the second surface 216. The conductive layer 222 may comprise any appropriate conductive material, including but not limited to, metals, such as copper, silver, nickel, palladium, gold, and aluminum, alloys thereof, and the like. In a specific embodiment, the conductive layer 222 may comprise a layer of nickel on the sidewall 226, a layer of palladium on the layer of nickel, and a final layer of gold on the layer of nickel. The conductive layer 222 may be formed by any process known in the art, such as plating. In one embodiment of the present description, the conductive layer 222 may be substantially conformal.

The integrated circuit package 110 may be attached to the conductive interposer 210 with a plurality of substrate-to-interposer interconnects 242. In one embodiment of the present description, the substrate-to-interposer interconnects 242 may extend between bond pads 148 on the second surface 134 of the electronic substrate 130 and bond pads 244 on the first surface 214 of the conductive interposer 210. The bond pads 244 on the first surface 214 of the conductive interposer 210 may be electrically attached to their respective conductive via 218. The substrate-to-interposer interconnects 242 may be any appropriate electrically conductive material or structure, including, but not limited to, solder balls, metal bumps or pillars, metal filled epoxies, or a combination thereof.

As further shown in FIG. 1, the electronic socket 310 may comprise a substantially rigid structure 312 having a first surface 314 and an opposing second surface 316, and at least one conductive pin 320 extending between the first surface 314 and the second surface 316. A first section 322 of the conductive pins 320 may be secured and reside within the rigid structure 312 of the electronic socket 310 and a second section 324 may extend beyond the first surface 314 of the rigid structure 312 of the electronic socket 310.

The electronic socket 310 may be in electrically contact with the conductive interposer 210 through the second section 324 of each of the conductive pins 320 of the electronic socket 310 extending into its respective conductive via 218 of the conductive interposer 210, wherein each of the second portions 324 of the conductive pins 320 may be biased against the conductive layer 220 of the conductive interposer 210. In one embodiment, the biasing of each of the second portions 324 of the conductive pins 320 against the conductive layer 220 of the conductive interposer 210 not only forms an electrical connection therebetween, but also physically attaches the conductive interposer 210 to the electronic socket 310. As further shown in FIG. 1, the electronic socket 310 may further include at least one flange 330 extending from the first surface 314 of the ridge structure 312 to assist in the alignment of the conductive interposer 210 to the electronic socket 310.

The rigid structure 312 may comprise any appropriate dielectric material, including, but not limited to, plastics, epoxies, and the like. The conductive pins 320 may comprise any appropriate conductive material, including but not limited to, metals, such as copper, silver, nickel, gold, and aluminum, alloys thereof, and the like.

As further shown in FIG. 1, the electronic socket 310 may be electrically attached to a carrier substrate 410, such as a board or motherboard. The carrier substrate 410 may have a first surface 412 and an opposing second surface 414. The carrier substrate 410 may comprise a plurality of dielectric material layers (not shown) and may further include conductive routes 418 or “metallization” (shown in dashed lines) extending through the carrier substrate 410, wherein at least one conductive route 418 may extend between at least one bond pad 422 in or on the first surface 412 of the carrier substrate 410 and at least one external components (not shown). The electronic socket 310 may be electrically attached to the carrier substrate 410 with the external interconnects 434 extending between the conductive pins 320 of the electronic socket 310 and the bond pads 422 in or on the first surface of the carrier substrate 410.

In another embodiment of the present description, as shown in FIG. 2, the electronic substrate 130 of the integrated circuit package 110 may be directly attached to the conductive interposer 210, such as by an adhesive, an epoxy, or a laminate process.

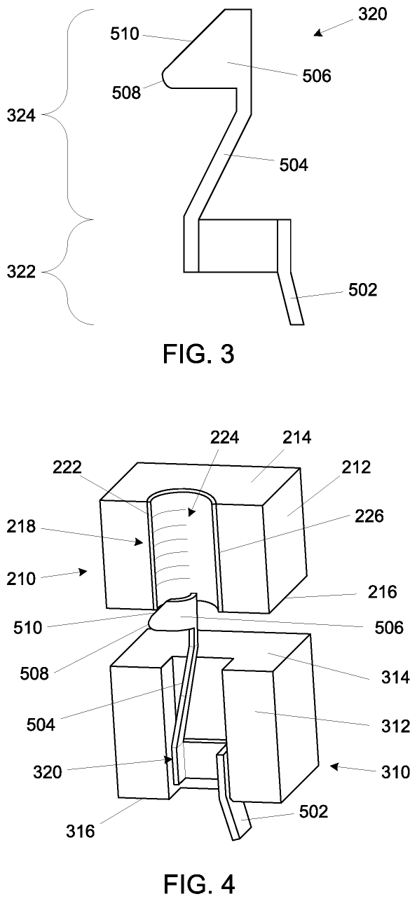

FIG. 3 illustrates one embodiment of a conductive pin 320 of the present description. As previously discussed, the conductive pin 320 may comprise a first section 322 and a second section 324. The second section 324 may comprise a resilient arm 504 and contact structure 506. The term “resilient” in the context of the present description is defined to mean a structure having the ability to recoil or spring back to an original shape or position after being bent, compressed, or otherwise deformed. The contact structure 506 may be position on an oppose side of the resilient arm 504 from the first section 322. The contact structure 506 may include a chamfered surface 510 to assist in the insertion of the conductive pin 320 in the conductive interposer 210 (see FIGS. 1 and 2), as will be discussed. The contact structure 506 may further include a contact surface 508, which will form a contact point with the conductive layer 222 of the conductive interposer 210 (see FIGS. 1 and 2), as will be discussed. In one embodiment of the present description, the contact surface 508 may be arcuate. The first section 322 may include an attachment tab 502 that may be used to attach to an interconnect structure, such as external interconnects 434 shown in FIGS. 1 and 2.

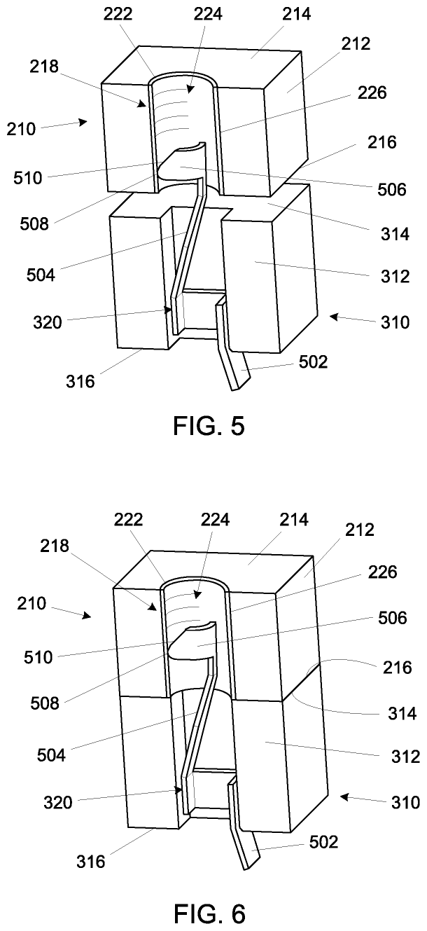

FIGS. 4-6 illustrate a process for connecting the conductive interposer 210 to the electronic socket 310. As shown in FIG. 4, the chamfered surface 510 of the contact structure 506 of the conductive pin 320 may be brought into contact with the conductive layer 222 of the conductive via 218 of the conductive interposer 210. As shown in FIG. 5, a force (not shown) may be applied to the conductive interposer 210, the electronic socket 310, or both, to deform the resilient arm 504 of the conductive pin 320, “wipe” the chamfered surface 510 against the conductive layer 222, and move a portion of the conductive pin 320 into the conductive via 218 of the conductive interposer 210, such that the contact surface 508 will “wipe” or travel along the conductive layer 222 of the conductive interposer 210 in a vertical or z-direction (see FIGS. 1 and 2) and, when an electrical signal is applied, a conductive path is formed therebetween. It is understood that the resilient nature of the resilient arm 504 will create a biasing force (not shown) on the conductive layer 222 of the conductive interposer 210 at the contact surface 508 of the contact structure 506 of the conductive pin 320. It is further understood that the angled shape of the chamfered surface 510 of the contact structure 506 will assist in aligning the conductive pin 320 to the conductive via 218 and will reduce the force needed to bring the contact surface 508 of the contact structure 506 into contact with the conductive layer 222 of the conductive interposer 210. As shown in FIG. 6, the conductive interposer 210 and the electric socket 310 may be brought into their final position by contacting the second surface 214 of the conductive interposer 210 with the first surface 312 of the electronic socket 310. As further shown in FIGS. 4-6, the attachment tab 502 may extend from the second surface 316 of the electronic socket 310.

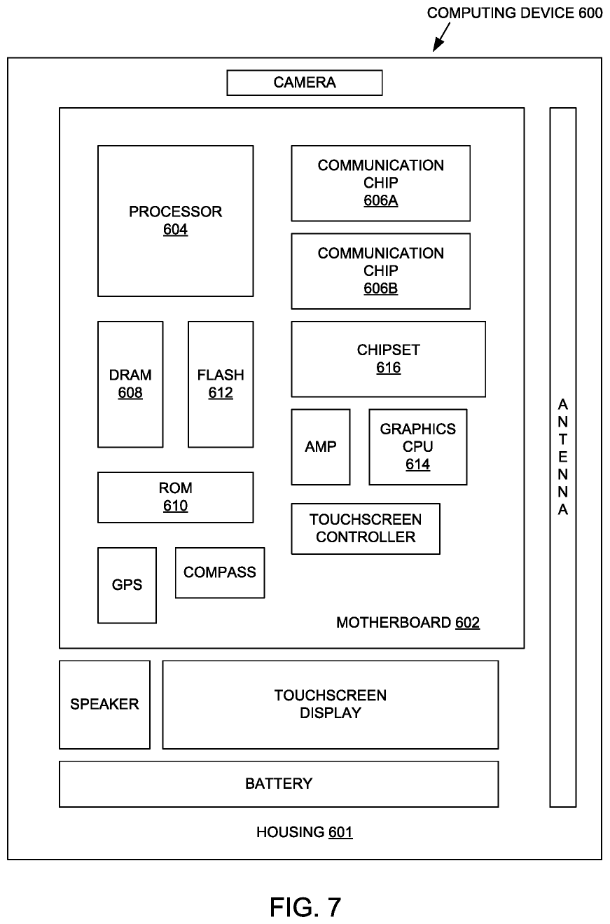

FIG. 7 illustrates an electronic or computing device 600 in accordance with one implementation of the present description. The computing device 600 may include a housing 601 having a board 602 disposed therein. The computing device 600 may include a number of integrated circuit components, including but not limited to a processor 604, at least one communication chip 606A, 606B, volatile memory 608 (e.g., DRAM), non-volatile memory 610 (e.g., ROM), flash memory 612, a graphics processor or CPU 614, a digital signal processor (not shown), a crypto processor (not shown), a chipset 616, an antenna, a display (touchscreen display), a touchscreen controller, a battery, an audio codec (not shown), a video codec (not shown), a power amplifier (AMP), a global positioning system (GPS) device, a compass, an accelerometer (not shown), a gyroscope (not shown), a speaker, a camera, and a mass storage device (not shown) (such as hard disk drive, compact disk (CD), digital versatile disk (DVD), and so forth). Any of the integrated circuit components may be physically and electrically coupled to the board 602. In some implementations, at least one of the integrated circuit components may be a part of the processor 604.

The communication chip enables wireless communications for the transfer of data to and from the computing device. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip or device may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device may include a plurality of communication chips. For instance, a first communication chip may be dedicated to shorter range wireless communications such as Wi-Fi and Bluetooth and a second communication chip may be dedicated to longer range wireless communications such as GPS, EDGE, GPRS, CDMA, WiMAX, LTE, Ev-DO, and others.

The term “processor” may refer to any device or portion of a device that processes electronic data from registers and/or memory to transform that electronic data into other electronic data that may be stored in registers and/or memory.

At least one of the integrated circuit components may be attached to the board 602 through an electronic socket electrically attached thereto, wherein the electronic socket includes a first surface, an opposing second surface, and at least one conductive pin, wherein the conductive pin includes a first section secured within the electronic socket and a second section having at least a portion thereof extending from the first surface of the electronic socket; a conductive interposer electrically attached to the electronic socket, wherein the conductive interposer includes a first surface, an opposing second surface, and at least one conductive via, wherein the conductive via comprises an opening extending between the first surface and the second surface and a conductive layer on a sidewall of the opening, and wherein the first surface of the electronic socket abuts the second surface of the conductive interposer; and wherein the portion of the second section of the at least one conductive pin extending from the first surface of the electronic socket extends into the at least one conductive via and is biased against the conductive layer of the at least one conductive via; and an integrated circuit package electrically attached to the first surface of the conductive interposer, wherein the integrated circuit package comprises an electronic substrate having a first surface and an opposing second surface, and at least one integrated circuit device electrically attached to the first surface of the electronic substrate.

In various implementations, the computing device may be a laptop, a netbook, a notebook, an ultrabook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder. In further implementations, the computing device may be any other electronic device that processes data.

It is understood that the subject matter of the present description is not necessarily limited to specific applications illustrated in FIGS. 1-7. The subject matter may be applied to other integrated circuit devices and assembly applications, as well as any appropriate electronic application, as will be understood to those skilled in the art.

The follow examples pertain to further embodiments and specifics in the examples may be used anywhere in one or more embodiments, wherein Example 1 is an integrated circuit assembly, comprising a conductive interposer including a first surface, an opposing second surface, and at least one conductive via, wherein the conductive via comprises an opening extending between the first surface and the second surface and a conductive layer on a sidewall of the opening; and an electronic socket having a first surface, an opposing second surface, and at least one conductive pin, wherein the conductive pin includes a first section secured within the electronic socket and a second section having at least a portion thereof extending from the first surface of the electronic socket; wherein the first surface of the electronic socket abuts the second surface of the conductive interposer; and wherein the portion of the second section of the at least one conductive pin extending from the first surface of the electronic socket extends into the at least one conductive via and is biased against the conductive layer of the at least one conductive via.

In Example 2, the subject matter of Example 1 can optionally include the second section of the at least one conductive pin comprises a resilient arm and a contact structure, wherein the resilient arm imparts the bias and the contact structure contacts the conductive layer of the at least one conductive via.

In Example 3, the subject matter of any of Examples 1 to 2 can optionally include the conductive layer being substantially conformal.

In Example 4, the subject matter of any of Examples 1 to 3 can optionally include the conductive layer comprising a metal.

Example 5 is an integrated circuit assembly comprising an integrated circuit package; a conductive interposer including a first surface, an opposing second surface, and at least one conductive via, wherein the conductive via comprises an opening extending between the first surface and the second surface and a conductive layer on a sidewall of the opening and wherein the integrated circuit package is electrically attached to the first surface of the conductive interposer; an electronic socket having a first surface, an opposing second surface, and at least one conductive pin, wherein the conductive pin includes a first section secured within the electronic socket and a second section having at least a portion thereof extending from the first surface of the electronic socket; wherein the first surface of the electronic socket abuts the second surface of the conductive interposer; and wherein the portion of the second section of the at least one conductive pin extending from the first surface of the electronic socket extends into the at least one conductive via and is biased against the conductive layer of the at least one conductive via.

In Example 6, the subject matter of Example 5 can optionally include the second section of the at least one conductive pin comprises a resilient arm and a contact structure, wherein the resilient arm imparts the bias and the contact structure contacts the conductive layer of the at least one conductive via.

In Example 7, the subject matter of any of Examples 5 to 6 can optionally include the conductive layer being substantially conformal.

In Example 8, the subject matter of any of Examples 5 to 7 can optionally include the conductive layer comprising a metal.

In Example 9, the subject matter of any of Examples 5 to 8 can optionally include the integrated circuit package comprising an electronic substrate having a first surface and an opposing second surface, and at least one integrated circuit device electrically attached to the first surface of the electronic substrate.

In Example 10, the subject matter of Example 9 can optionally include the second surface of the electronic substrate of the integrated circuit package being electrically attached to the first surface of the conductive interposer.

In Example 11, the subject matter of Example 9 can optionally include a heat dissipation device thermally attached to the at least one integrated circuit device.

In Example 12, the subject matter of Example 11 can optionally include the heat dissipation device being attached to the first surface of the electronic substrate.

Example 13 is an electronic system comprising a board; an electronic socket electrically attached to the board, wherein the electronic socket includes a first surface, an opposing second surface, and at least one conductive pin, wherein the conductive pin includes a first section secured within the electronic socket and a second section having at least a portion thereof extending from the first surface of the electronic socket; a conductive interposer electrically attached to the electronic socket, wherein the conductive interposer includes a first surface, an opposing second surface, and at least one conductive via, wherein the conductive via comprises an opening extending between the first surface and the second surface and a conductive layer on a sidewall of the opening, and wherein the first surface of the electronic socket abuts the second surface of the conductive interposer; and wherein the portion of the second section of the at least one conductive pin extending from the first surface of the electronic socket extends into the at least one conductive via and is biased against the conductive layer of the at least one conductive via; and an integrated circuit package electrically attached to the first surface of the conductive interposer.

In Example 14, the subject matter of Example 13 can optionally include the second section of the at least one conductive pin comprises a resilient arm and a contact structure, wherein the resilient arm imparts the bias and the contact structure contacts the conductive layer of the at least one conductive via.

In Example 15, the subject matter of any of Examples 13 to 14 can optionally include the conductive layer being substantially conformal.

In Example 16, the subject matter of any of Examples 13 to 15 can optionally include the conductive layer comprising a metal.

In Example 17, the subject matter of any of Examples 13 to 16 can optionally include the integrated circuit package comprising an electronic substrate having a first surface and an opposing second surface, and at least one integrated circuit device electrically attached to the first surface of the electronic substrate.

In Example 18, the subject matter of Example 17 can optionally include the second surface of the electronic substrate of the integrated circuit package being electrically attached to the first surface of the conductive interposer.

In Example 19, the subject matter of Example 17 can optionally include a heat dissipation device thermally attached to the at least one integrated circuit device.

In Example 20, the subject matter of Example 19 can optionally include the heat dissipation device being attached to the first surface of the electronic substrate.

Having thus described in detail embodiments of the present invention, it is understood that the invention defined by the appended claims is not to be limited by particular details set forth in the above description, as many apparent variations thereof are possible without departing from the spirit or scope thereof.

What is claimed is:

1. An integrated circuit assembly, comprising:
a conductive interposer including a first surface, an opposing second surface, and at least one conductive via, wherein the conductive via comprises an opening extending between the first surface and the second surface and a conductive layer on a sidewall of the opening; and
an electronic socket having a first surface, an opposing second surface, and at least one conductive pin, wherein the conductive pin includes a first section secured within the electronic socket and a second section having at least a portion thereof extending from the first surface of the electronic socket; wherein the first surface of the electronic socket abuts the second surface of the conductive interposer; and wherein the portion of the second section of the at least one conductive pin extending from the first surface of the electronic socket extends into the at least one conductive via and is biased against the conductive layer of the at least one conductive via.

2. The integrated circuit assembly of claim 1, wherein the second section of the at least one conductive pin comprises a resilient arm and a contact structure, wherein the resilient arm imparts the bias and the contact structure contacts the conductive layer of the at least one conductive via.

3. The integrated circuit assembly of claim 1, wherein the conductive layer is substantially conformal.

4. The integrated circuit assembly of claim 1, wherein the conductive layer comprises a metal.

5. An integrated circuit assembly, comprising:
an integrated circuit package;
a conductive interposer including a first surface, an opposing second surface, and at least one conductive via, wherein the conductive via comprises an opening extending between the first surface and the second surface and a conductive layer on a sidewall of the opening and wherein the integrated circuit package is electrically attached to the first surface of the conductive interposer;
an electronic socket having a first surface, an opposing second surface, and at least one conductive pin, wherein the conductive pin includes a first section secured within the electronic socket and a second section having at least a portion thereof extending from the first surface of the electronic socket; wherein the first surface of the electronic socket abuts the second surface of the conductive interposer; and wherein the portion of the second section of the at least one conductive pin extending from the first surface of the electronic socket extends into the at least one conductive via and is biased against the conductive layer of the at least one conductive via.

6. The integrated circuit assembly of claim 1, wherein the second section of the at least one conductive pin comprises a resilient arm and a contact structure, wherein the resilient arm imparts the bias and the contact structure contacts the conductive layer of the at least one conductive via.

7. The integrated circuit assembly of claim 1, wherein the conductive layer is substantially conformal.

8. The integrated circuit assembly of claim 1, wherein the conductive layer comprises a metal.

9. The integrated circuit assembly of claim 1, wherein the integrated circuit package comprising an electronic substrate having a first surface and an opposing second surface, and at least one integrated circuit device electrically attached to the first surface of the electronic substrate.

10. The integrated circuit assembly of claim 9, wherein the second surface of the electronic substrate of the integrated circuit package is electrically attached to the first surface of the conductive interposer.

11. The integrated circuit assembly of claim 9, further comprising a heat dissipation device thermally attached to the at least one integrated circuit device.

12. The integrated circuit assembly of claim 11, wherein the heat dissipation device is attached to the first surface of the electronic substrate.

13. An electronic system comprising:
a board;
an electronic socket electrically attached to the board, wherein the electronic socket includes a first surface, an opposing second surface, and at least one conductive pin, wherein the conductive pin includes a first section secured within the electronic socket and a second section having at least a portion thereof extending from the first surface of the electronic socket;
a conductive interposer electrically attached to the electronic socket, wherein the conductive interposer includes a first surface, an opposing second surface, and at least one conductive via, wherein the conductive via comprises an opening extending between the first surface and the second surface and a conductive layer on a sidewall of the opening, and wherein the first surface of the electronic socket abuts the second surface of the conductive interposer; and wherein the portion of the second section of the at least one conductive pin extending from the first surface of the electronic socket extends into the at least one conductive via and is biased against the conductive layer of the at least one conductive via; and
an integrated circuit package electrically attached to the first surface of the conductive interposer.

14. The electronic system of claim 13, wherein the second section of the at least one conductive pin comprises a resilient arm and a contact structure, wherein the resilient arm imparts the bias and the contact structure contacts the conductive layer of the at least one conductive via.

15. The electronic system of claim 13, wherein the conductive layer is substantially conformal.

16. The electronic system of claim 13, wherein the conductive layer comprises a metal.

17. The electronic system of claim 13, wherein the integrated circuit package comprising an electronic substrate having a first surface and an opposing second surface, and at least one integrated circuit device electrically attached to the first surface of the electronic substrate.

18. The electronic system of claim 17, wherein the second surface of the electronic substrate of the integrated circuit package is electrically attached to the first surface of the conductive interposer.

19. The electronic system of claim 17, further comprising a heat dissipation device thermally attached to the at least one integrated circuit device.

20. The electronic system of claim 19, wherein the heat dissipation device is attached to the first surface of the electronic substrate.
